(19) United States
(12) Patent Application Publication
(10) Pub. No.: US 2026/0299655 A1
(43) Pub. Date: Oct. 1, 2026

(54) SYSTEMS AND METHODS FOR LEAKAGE PROTECTION

(71) Applicant: Quanta Computer Inc., Taoyuan City (TW)

(72) Inventors: Yi-Chieh CHEN, Taoyuan City (TW); Yueh-Chang WU, Taoyuan City (TW); Te-Chuan WANG, Taoyuan City (TW); Samuel CHATELIER, Taoyuan City (TW); Shu-Cheng LI, Taoyuan City (TW)

(21) Appl. No.: 19/090,142

(22) Filed: Mar. 25, 2025

(51) Int. Cl. G06F 1/20; G01M 3/16; H05K 1/02

(52) U.S. Cl. CPC G06F 1/20; G01M 3/16; H05K 1/0203; H05K 2201/064; H05K 2201/10151; H05K 2201/10212

(57) ABSTRACT

A computing system comprising a cooling system and a printed circuit board (PCB) thermally coupled with the cooling system is disclosed. The PCB can have a microchip embedded onto it. The computing system may also include at least one leakage sensor embedded on the PCB proximate to the microchip. The at least one leakage sensor can be shaped to define a boundary which encloses a portion of the PCB that contains the microchip.

FIELD OF THE INVENTION

The present invention relates generally to an embedded leakage sensor, and more specifically, to methods and systems for leakage protection on a printed circuit board (PCB).

### BACKGROUND OF THE INVENTION

Recent advancements in the design of computing systems, such as computing servers, have led to a significant increase in their components'power consumption. Central Processing Units (CPUs), Graphics Processing Units (GPUs), Neural Processing Units (NPUs), and Tensor Processing Units (TPUs) all may consume large amounts of power, and may therefore generate large amounts of heat. Traditional methods of cooling down components with high thermal loads, such as air-cooling, can present challenges due to the limited ability of these systems to maintain a desirable operating temperature.

The use of fluid materials in cooling systems presents one method of heat management for high-performance systems. The higher thermal conductivity of various fluid materials allows for more efficient cooling systems. For example, liquid metal thermal interface materials (TIMs) can be used to improve the performance of traditional air-cooling systems. For certain thermal loads, liquid cooling systems, which use a flowing liquid to transfer heat away from components, can be used. These fluid-based systems can leak, which can cause short circuits and other damage to PCBs and other electronic components of the computing system. Some methods of containing fluid coolants, such as sponges, epoxies, and fiber materials, can degrade over time, and cannot alert the system when a leak has occurred. Traditional leakage sensors, while they can detect leaks, cannot protect the components from damage or data loss. Therefore, there is a need for systems, methods, and apparatuses to detect fluid coolant leaks and protect computing systems from damage.

### SUMMARY OF THE INVENTION

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

According to certain aspects of the present disclosure, a computing system comprising a cooling system and a PCB thermally coupled with the cooling system is shown. The PCB can have a microchip embedded onto it. The computing system may also include at least one leakage sensor embedded on the PCB proximate to the microchip. The at least one leakage sensor can be shaped to define a boundary which encloses a portion of the PCB that contains the microchip.

According to a configuration of the above implementation, the at least one leakage sensor can output a leakage signal to trigger a leakage alert in response to a change in electrical resistance.

According to another configuration of the above implementation, the computing system may further comprise a baseboard management controller (BMC) communicatively coupled with the leakage sensors. The leakage sensor can be configured to detect a fluid leak and notify the BMC that the fluid leak has occurred.

According to a further configuration of the above implementation, the BMC can be configured to cause the shutdown of one or more components of the computing system in response to a fluid leak.

In a further aspect of the above implementation, the leakage sensor can be configured to detect a location of the fluid leak. Based on this location, the BMC can cause the shutdown of a respective portion of the computing system.

In yet a further aspect of the above implementation, the cooling system includes a cold plate configured to circulate a fluid as a liquid coolant.

According to another aspect of the present disclosure, the cold plate can be in direct contact with the microchip.

According to a configuration of the above implementation, the microchip may further comprise one or more channels configured to allow the liquid coolant to flow through the channels.

According to another configuration of the above implementation, the cooling system can include a cold plate and a heat sink. The heat sink can have a plurality of cooling channels through which a fluid flows as a liquid coolant.

In a further aspect of the above implementation, only the microchip is embedded within the boundary.

In yet a further aspect of the above implementation, the cooling system includes a heat sink. The heat sink may be thermally coupled with a liquid metal thermal interface material.

According to a configuration of the above implementation, the at least one leakage sensor can include one or more wires configured to transmit an electrical current. A change in resistance across the one or more wires may be indicative of a presence of a leaked fluid.

According to a further configuration of the above implementation, the at least one leakage sensor can include an electrically conductive band of material. A change in resistance in the electrically conductive band of material may be indicative of a presence of a leaked fluid.

In yet a further aspect of the above implementation, a computer-implemented method is provided. The method includes detecting a presence of a fluid in contact with one or more leakage sensors. The one or more leakage sensors can be embedded proximate to a microchip on a printed circuit board of a computing system. The method also includes notifying a baseboard management controller (BMC) embedded on the printed circuit board that a fluid leak has occurred.

According to a further configuration of the above implementation, the method further includes transmitting a signal to cause shutdown of one or more components of the computing system in response to the detection of a fluid leak.

In a further aspect of the above implementation, the leakage sensor may comprise one or more wires configured to transmit an electrical current. A change in resistance across the one or more wires can indicate a presence of a fluid.

In yet another aspect of the above implementation, the leakage sensor can comprise an electrically conductive band of material. A change in resistance in the band can indicate a presence of a fluid.

According to certain aspects of the present disclosure, a computer-implemented method is provided. The computer-implemented method may comprise detecting a presence of a fluid in contact with one or more leakage sensors. The one or more leakage sensors may be embedded proximate to a microchip on a printed circuit board. The method may also comprise notifying a BMC of the computing system that a fluid leak has occurred and has been detected by the leakage sensors.

According to a configuration of the above implementation, the method may comprise transmitting a signal to cause the computing system to shut down in response to the detection of a fluid leak.

In a further aspect of the above implementation, the method may further comprise detecting a location of the fluid leak with respect to the computing system. The method may also comprise transmitting a signal using the BMC to cause shutdown of a respective portion of the computing system associated with the location of the fluid leak.

In yet a further aspect of the above implementation, the one or more leakage sensors are configured to define a boundary. The boundary can enclose a portion of the PCB that contains the microchip.

According to a configuration of the above implementation, only the microchip is within the boundary.

In a further aspect of the above implementation, the one or more leakage sensors include one or more wires configured to transmit an electrical current. A change in resistance across the one or more wires may be indicative of a presence of a leaked fluid.

In yet another aspect of the above implementation, the at least one leakage sensor includes an electrically conductive band of material. A change in resistance in the electrically conductive band of material may be indicative of a presence of a leaked fluid.

According to a configuration of the above implementation, the method may further include activating a mechanism for containing the fluid leak.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure, and its advantages and drawings, will be better understood from the following description of representative embodiments together with reference to the accompanying drawings. These drawings depict only representative embodiments, and are therefore not to be considered as limitations on the scope of the various embodiments or claims.

FIG. 1 is a side view showing a die embedded on a printed circuit board (PCB) with an air-cooling mechanism, according to certain aspects of the present disclosure.

FIG. 2 is a top view showing a die and a leakage sensor embedded on a PCB, according to certain aspects of the present disclosure.

FIG. 3A is a side view showing a die embedded on a PCB with a liquid cooling mechanism, according to certain aspects of the present disclosure.

FIG. 3B is a side view showing a die embedded on a PCB with a liquid cooling mechanism and a leak, according to certain aspects of the present disclosure.

FIG. 4 is a side view showing a die embedded on a PCB with a direct liquid cooling mechanism, according to certain aspects of the present disclosure.

FIG. 5 is another side view showing a die embedded on a PCB with a direct liquid cooling mechanism, according to certain aspects of the present disclosure.

FIG. 6 is a diagram of a leakage sensor, according to certain aspects of the present disclosure.

FIG. 7 is a flowchart showing a method of protecting a computing system after a leak, according to certain aspects of the present disclosure.

### DETAILED DESCRIPTION

A computing system comprising a cooling system and a PCB thermally coupled with the cooling system is disclosed. The PCB can have a microchip embedded onto it. The computing system may also include at least one leakage sensor embedded on the PCB proximate to the microchip. The at least one leakage sensor can be shaped to define a boundary which encloses a portion of the PCB that contains the microchip.

Various embodiments are described with reference to the attached figures, where like reference numerals are used throughout the figures to designate similar or equivalent elements. Each reference numeral identifies the figure in which the reference numeral first appears based on the first digit (for three-digit reference numerals) or the first two digits (for four-digit reference numerals) corresponding to the figure numeral of the figure. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation.” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively. Additionally, words of direction, such as “top,” “bottom,” “left,” “right,” “above,” and “below” are intended to relate to the equivalent direction as depicted in a reference illustration; as understood contextually from the object(s) or element(s) being referenced, such as from a commonly used position for the object(s) or element(s); or as otherwise described herein.

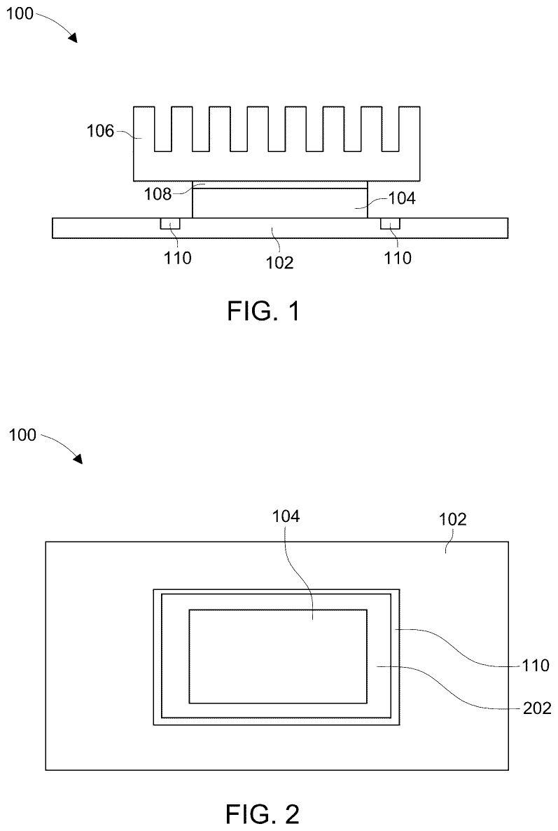

Referring to FIG. 1, a side view of a configuration 100 of a computing system comprising a die 104 embedded on a PCB 102 with an air-cooling mechanism is shown, according to example embodiments. This configuration 100 may represent a microchip installed or otherwise operably coupled within a computing system. The microchip apparatus can represent a central processing unit (CPU), a graphics processing unit (GPU), a tensor processing unit (TPU) a neural processing unit (NPU), or any other microchip. In this example embodiment, the die 104 is embedded onto the PCB 102, which can be a motherboard, daughterboard, graphics card, expansion card, or other circuit board of the computing system. Bonded to the top of the die 104, there can be a thermal interface material (TIM) 108. The TIM 108 is a paste, epoxy, gel, pad, fluid, or other material that has a certain thermal conductivity and is designed to transfer heat from the die 104 to the heat sink 106. For example, the TIM 108 can be a silicone-based thermal paste or thermal pad. In other example embodiments, the TIM 108 can be a liquid metal.

Thermally coupled with the TIM 108, there may be a heat sink 106. In the example embodiment shown in FIG. 1, the heat sink 106 is an air-cooled heat sink 106. Air-cooled cooling mechanisms utilize air as the conductive fluid to transfer heat away from the TIM 108, which transfers heat from the die 104, thereby cooling the die 104 during operation. The air-cooled heat sink 106 may be a passive heat sink, using the presence of atmospheric air to cool itself. In some other example embodiments, the air-cooled heat sink 106 may utilize a forced air induction method such as a fan or air blower.

The liquid metal TIM 108 may be electrically conductive. In this case, the liquid metal TIM 108 can cause electrical shorts and other adverse effects if it leaks onto the PCB 102 or the die 104. In some example embodiments, the leakage sensors 110 may be embedded onto the PCB 102 to help detect and potentially protect the electronics of the PCB 102 from leakage. In FIG. 1, the leakage sensors 110 are embedded on the PCB at a short distance on each side from where the die 104 is embedded. The leakage sensors 110 may be wires, traces, films, or belts that carry a monitored electrical charge. The charge of the leakage sensors 110 can be monitored by a baseboard management controller (BMC) of the PCB 102, a CPU of the computing system, a microcontroller, or another processor. If the liquid metal TIM 108 leaks onto the PCB 102, the leakage sensors 110 will experience a change in electrical resistance upon contact with the liquid metal TIM 108. This change in electrical resistance can be detected by the system and used to determine that a fluid leak of the liquid metal TIM 108 has occurred.

Referring to FIG. 2, a top view of the configuration 100 of a computing system comprising a die and a leakage sensor embedded on a PCB is shown, according to example embodiments. The top view 200 shows how the leakage sensor 110 may be configured in a way that surrounds or otherwise encloses a plane of the PCB 102 that contains the embedded die 104. As shown, the leakage sensor 110 is configured as a rectangle slightly larger than the footprint of the die 104 embedded onto the PCB 102. Other shapes and configurations of the leakage sensors 110 and the die 104 may be possible as well. This encloses the die 104 with respect to the PCB 102, ensuring that any fluid that leaks from the proximity of the die 104 will be detected by the leakage sensors 110.

In some example embodiments, there may be an area of the PCB 102 in between the perimeter of the leakage sensors 110 and the die 104 embedded on the PCB 102 where neither the die 104 nor the leakage sensors 110 are embedded. This area may also be void of other electronic components and may be referred to as a keep-out zone 202. The keep-out zone 202 is an area of the PCB 102 between the leakage sensors 110 and the die 104 that does not contain electronic components that may be vulnerable to a fluid leak. Therefore, if fluid leaks from the proximity of the die 104 onto the keep-out zone 202, damage to the computing system and the PCB 102 may be limited, and the leakage sensor 110 may detect the presence of a fluid leak. The protection provided by the keep-out zone 202 can be implemented in various ways. For example, the keep-out zone 202 may only contain the traces and connections needed to connect the die 104 to the rest of the PCB 102. This can ensure that only the die 104 is damaged in the event of a fluid leak. In other configurations, the keep-out zone 202 may comprise a protective coating, cover, film, or other structure meant to isolate and protect the keep-out zone 202 from a leak. In some further configurations, the keep-out zone 202 may utilize a sponge, epoxy, or a mechanical device that is activated in response to the detection of a fluid leak by the leakage sensors 110. This can contain the fluid leak to the area of the keep-out zone 202, protecting the rest of the PCB 102 from any fluid.

In some other example embodiments, the keep-out zone 202 may be further separated from the PCB 102. For example, the area delineated by the leakage sensors 110 may comprise a separate daughterboard or expansion card operably coupled with the PCB 102. In this case, the separation of the keep-out zone 202, the die 104, and the leakage sensors 110 may protect the rest of the PCB 102 from a fluid leak.

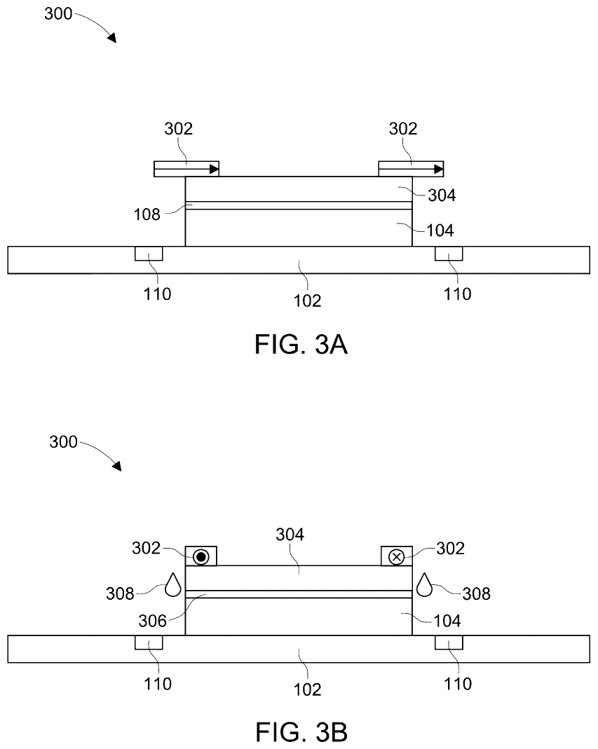

Referring to FIG. 3A, a side view of a configuration 300 of a computing system comprising a die 104 embedded on a PCB 102 with a liquid cooling mechanism is shown, according to example embodiments. In some computing systems, liquid cooling systems may provide improved thermal management properties. Multiple configurations of liquid cooling systems are possible. FIG. 3A shows a liquid cooling system utilizing a cold plate 304 thermally coupled with a TIM 108, which is in turn thermally coupled with the die 104. The die 104 may transfer heat to the TIM 108, which then can transfer it to the cold plate 304. The cold plate 304 can be a variety of devices. For example, the cold plate 304 may be a water block comprising a heat exchange mechanism, internal channels for fluid to flow through, and external connections for fluid.

The cold plate 304 may be connected to one or more external fluid transport connections 302. The external fluid may enter the heat exchange mechanism, absorb heat from the cold plate 304 as it transfers through the internal channels, and then exit the heat exchange mechanism. This heated fluid transfers heat away from the die 104, and then can be cooled down with a fan, condenser tower, or other external cooling mechanism. The external fluid transport connections 302 can be pipes, tubes, or other fluid transport conduits. The thermal fluid they transport can be water, a mineral oil-based substance, an alcohol substance, or another fluid with thermal conductive properties. In some example embodiments, the thermal fluid can be a liquid metal substance.

Referring to FIG. 3B, a side view of the configuration 300 of the computing system comprising a die 104 embedded on a PCB 102 with a liquid cooling mechanism and a fluid leak 308 is shown, according to example embodiments. In this scenario, a fluid leak 308 has occurred. In some example embodiments, the fluid leak 308 could be from a liquid metal TIM 108, like the embodiments described above in air-cooled systems. In this case, the fluid leak 308 would comprise the liquid metal TIM 108 and would be detected by the leakage sensors 110.

In some other example embodiments, the fluid leak 308 may be thermal fluid from the liquid cooling system. The fluid leak 308 may therefore originate from the cold plate 304, the fluid transport connections 302, and/or a cold plate TIM 306. The cold plate TIM 306 can couple the cold plate 304 to the die 104. The cold plate TIM 306 can be a paste, epoxy, gel, pad, fluid, or other material that has a certain thermal conductivity and is designed to transfer heat from the die 104 to the cold plate TIM 306. When a fluid leak 308 occurs, fluid may spill or leak onto the PCB 102 proximate to the cold plate 304, the cold plate TIM 306, the fluid transport connections 302, and/or the die 104. This fluid leak 308 may then be detected by the leakage sensors 110 embedded in the PCB 102.

In further configurations, the leakage sensors 110 may be configured to enclose a plane of the PCB 102 that includes the footprint of the fluid transport connections 302. As the fluid transport connections 302 may connect to external fluid sources, the fluid transport connections 302 may pass over various areas of the PCB 102. The leakage sensors 110 may be shaped to accommodate the footprint of these fluid transport connections 302. Alternatively, or additionally, there may be multiple sets of leakage sensors 110 embedded onto different areas of the PCB 102.

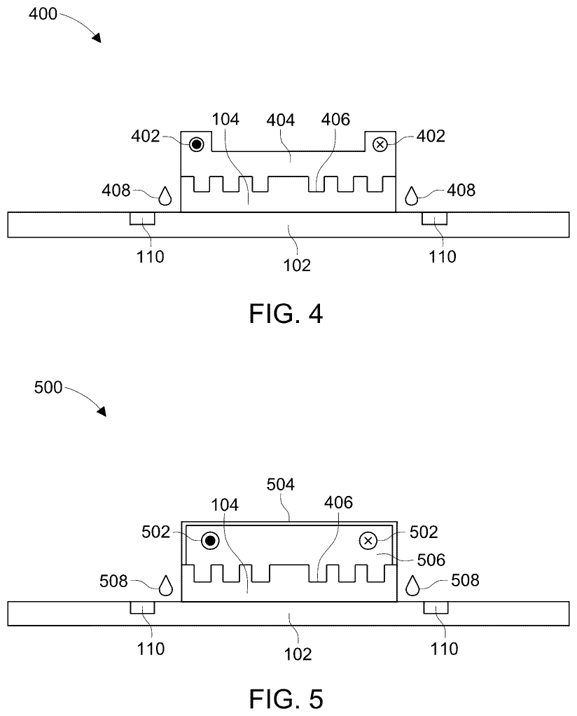

Referring to FIG. 4, a side view of a configuration 400 of a computing system comprising the die 104 embedded on a PCB 102 with a direct liquid cooling mechanism is shown, according to example embodiments. Direct liquid cooling comprises a variety of liquid cooling technologies that bring the thermal fluid into closer contact with the die 104 than configurations that use a cold plate may allow for. In this example embodiment, the die 104 has multiple channels 406 etched onto a surface of the die 104. The channels 406 may take various forms, such as rectangular channels, curved grooves, pits, tubes, or other configurations. The channels 406 are configured to thermally couple with the direct liquid cooling block 404. Through this thermal coupling, and the increased surface area of the die 104 due to the channels 406, the die 104 may be capable of transferring heat more efficiently into the direct liquid cooling block 404. The direct liquid cooling block may be made of a material capable of absorbing this heat and thereby cooling the die 104.

To cool the direct liquid cooling block 404, it may comprise one or more fluid transport connections 402. These fluid transport connections 402 may be conduits carved or etched into the direct liquid cooling block 404. They may also comprise tubing, piping, or other fluid transport mechanisms that carry heat away from the direct liquid cooling block 404. The fluid transport connections 402 may be configured to transport thermal fluid directly into the direct liquid cooling block 404. The direct liquid cooling block 404 may then, in turn, comprise structures intended to allow heat to dissipate from the direct liquid cooling block 404 into the thermal fluid. For example, the direct liquid cooling block 404 may comprise micro channels that allow thermal fluid to flow through the body of the direct liquid cooling block 404. This allows for heat to be absorbed by the thermal fluid and carried away from the direct liquid cooling block 404. In some other example configurations, the direct liquid cooling block 404 may comprise a porous material such as epoxy or a 3D-printed metal intended to increase the internal surface area of the direct liquid cooling block 404. This configuration allows thermal fluid to permeate the structure of the direct liquid cooling block 404.

In some scenarios, the direct liquid cooling block 404 or the fluid transport connections 402 can leak fluid. In this case, a leak 408 can occur. When the leak 408 occurs, fluid may leak from the direct liquid cooling block 404 or the fluid transport connections onto the die 104 and the PCB 102. When the leak 408 contacts the leakage sensors 110, the leakage sensors 110 can be configured to detect the presence of the leak 408 in response to the fluid coming in contact. As noted above, this may be done by the leakage sensors 110, a BMC, or another microcontroller detecting a change in resistance in the leakage sensors 110. In some example embodiments, the leakage sensors 110 may be configured to send a signal to the BMC or another microcontroller of the computing system when the leak 408 is detected. This signal may then cause a shutdown of the computing system, part of the computing system, or the activation of a mechanism meant to protect the computing system from damage or memory loss.

Referring to FIG. 5, a side view of a configuration 500 of a computing system comprising the die 104 embedded on a PCB 102 with a direct liquid cooling mechanism is shown, according to example embodiments. In this example embodiment, the direct liquid cooling mechanism is configured to allow for the direct flow of thermal fluid through the channels 406 of the die 104. As shown in FIG. 5, the cold plate enclosure 504 is shaped to create a space 506 for fluid to flow through. Within this space 506, there may be one or more fluid transport connections 502 configured to carry thermal fluid into and/or out of the cold plate enclosure 504. The space 605 may comprise channels, piping, cavities, foam, or other configurations intended to increase the interior surface area of the cold plate enclosure 504 and change the heat conductivity of the cold plate enclosure 504.

Thermal fluid within the space 506 may flow over the one or more channels 406 disposed on the die 104. The thermal fluid may absorb heat from the die 104 while flowing in proximity to these channels. The thermal fluid may then exit the cold plate enclosure 504 by the fluid transport connections 502. In some example embodiments, this arrangement allows for the direct absorption of heat from the die 104 by the thermal fluid. In other example embodiments, the cold plate enclosure 504 may be configured to absorb heat from the die 104. The thermal fluid flowing within the space 506 may then absorb heat from the cold plate enclosure 504 and transport it away from the direct liquid cooling assembly.

In some example embodiments, the direct liquid cooling assembly may experience a leak 508. This leak 508 may originate from the cold plate enclosure 504, the space 506, or the fluid transport connections 502. The leak 508 may leak from these areas onto the die 104 or the PCB 102. In these scenarios, the leakage sensors 110 may detect a presence of the leak 508 upon contact of the fluid of the leak 508 with the leakage sensors 110. As described above, the leakage sensors 110 may transmit a signal indicating the presence of the leak 508 to a BMC or microcontroller of the computing system or PCB 102. In some other embodiments, the leakage sensors 110 may detect a location of the leak 508 and transmit information indicating the location to a BMC or microcontroller of the computing system or PCB 102.

When the BMC or microcontroller is notified of the presence of a leak 508, the BMC or microcontroller may transmit a signal to cause the cold plate enclosure 504 to contain or mitigate the leak 508. For example, the cold plate enclosure 504 may activate a mechanism to drain the space 506 of thermal fluid to prevent further leakage. In some other example embodiments, the BMC or microcontroller may transmit a signal to cause the computing system, PCB 102, or die 104 to shut down to prevent or mitigate damage from the leak 508. The shutdown signal may be selective based on a detected location of the leak 508.

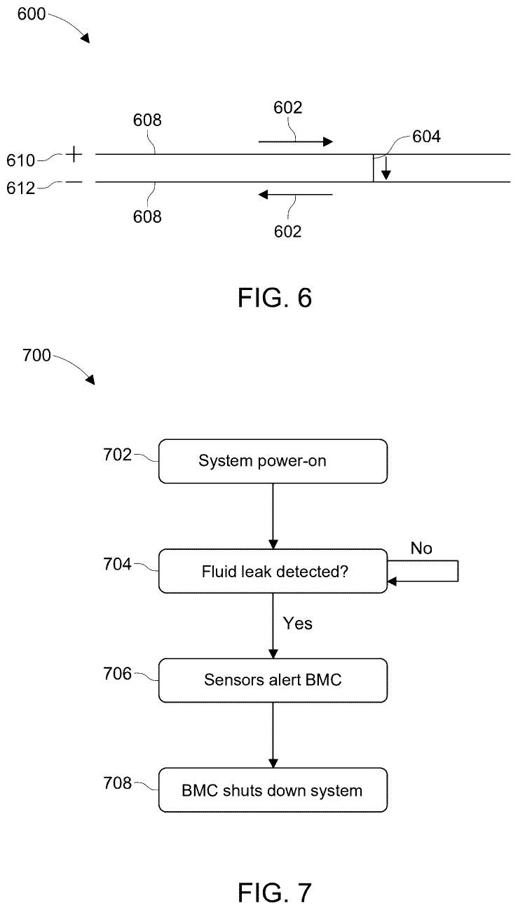

Referring to FIG. 6, a diagram 600 of a leakage sensor is shown, according to example embodiments. The leakage sensor may comprise one or more wires, traces, connections, or other devices capable of carrying electric charge 602. The leakage sensor may comprise a positive terminal 610, a negative terminal 612, and main wires 608 arranged in a substantially parallel configuration. The main wires 608 may connect the positive terminal 610 to the negative terminal 612 and be configured to carry the electric charge 602 from one terminal to the other. The electric charge 602 may cross over from one main wire 608 to the other at one or more points 604.

When a leak occurs, the fluid may contact the one or more main wires 608 of the leakage sensor. Due to the conductivity of the fluid, the electrical resistance of the circuit created in the main wires 608 of the leakage sensor may change. This change in resistance can lead to a change in the electric charge 602 flowing through the main wires 608. This change in the electric charge 602 may be detected by the positive terminal 610 or the negative terminal 612. The change in the electric charge 602 may also be detected by other sensors of the leakage sensor, or by a BMC or microcontroller of the computing system.

Referring to FIG. 7, a flowchart illustrating a method 700 of protecting a computing system after a leak is shown, according to example embodiments. In step 702 of the method 700, the system can power-on and begin normal operations. During this step, electric current is flowing through the computing system and the PCBs associated with it. Additionally, the cooling systems of any components coupled with the computing system are active, and fluid may be flowing through any liquid cooling systems.

In step 704 of the method 700, a leakage sensor, BMC, microcontroller, CPU, or other processor of the computing system may continuously check for the presence of a fluid leak in the computing system. Other sensors or controllers in the computing system may also participate in this monitoring process. If no fluid leak is detected, the computing system will operate normally. If a leak is detected, step 706 of the method 700 shows how a BMC or other processor of the system may receive an alert indicating a presence of a fluid leak. Step 706 of the method 700 may also comprise receiving an indication, from a leakage sensor of the computing system, of a location of the fluid leak.

In some example embodiments, step 706 of the method 700 may also include notifying a user or a second computing system of the presence of a fluid leak in the first computing system. This notification may be sent by a network, the cloud, or on a display or user interface of the first computing system. The notification can include information associated with the fluid leak, such as location, duration, a severity indicator, and any protective measures that the computing system has taken.

In step 708 of the method 700, the BMC or another controller of the computing system may transmit a signal causing the computing system to shut down in response to the detection of a fluid leak. In step 708, the presence and/or location of a fluid leak has been determined. To prevent damage to physical components of the computing system, or data loss from storage and memory components, the BMC can shut down the system. Step 708 may also comprise specialized instructions sent by the BMC causing the system to save, preserve, or otherwise protect data prior to the shutdown. This can ensure the protection of data when a fluid leak in a computing system is detected.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any shown or particular application.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above described embodiments. Rather, the scope of the disclosure should be defined in accordance with the following claims and their equivalents.

What is claimed is:

1. A computing system comprising:
a cooling system;
a printed circuit board (PCB) thermally coupled with the cooling system;
a microchip embedded on the PCB; and
at least one leakage sensor embedded on the PCB proximate to the microchip, wherein the at least one leakage sensor is shaped to define a boundary, the boundary enclosing a portion of the PCB that contains the microchip.

2. The computing system of claim 1, wherein, in response to a change in electrical resistance, the at least one leakage sensor outputs a leakage signal to trigger a leakage alert.

3. The computing system of claim 1, further comprising a baseboard management controller (BMC), the at least one leakage sensor being communicatively coupled with the BMC and configured to
detect, based on contact between a fluid of the cooling system and any portion of the at least one leakage sensor, a fluid leak; and
notify the BMC that the fluid leak has occurred.

4. The computing system of claim 3, wherein, in response to being notified that the fluid leak has occurred, the BMC is configured to cause shutdown of one or more components of the computing system.

5. The computing system of claim 3, wherein the at least one leakage sensor is further configured to
detect a location of the fluid leak, and
cause shutdown, via the BMC, of a respective portion of the computing system associated with the location of the fluid leak.

6. The computing system of claim 1, wherein the cooling system includes a cold plate configured to circulate a fluid as a liquid coolant.

7. The computing system of claim 6, wherein the cold plate is in direct contact with the microchip.

8. The computing system of claim 1, wherein the cooling system includes a cold plate and a heat sink, the heat sink having a plurality of cooling channels through which a fluid flows as a liquid coolant.

9. The computing system of claim 1, wherein only the microchip is embedded within the boundary.

10. The computing system of claim 1, wherein the cooling system includes a heat sink, the heat sink being thermally coupled with a liquid metal thermal interface material.

11. The computing system of claim 1, wherein the at least one leakage sensor includes one or more wires configured to transmit an electrical current, a change in resistance across the one or more wires being indicative of a presence of a leaked fluid.

12. The computing system of claim 1, wherein the at least one leakage sensor includes an electrically conductive band of material, a change in resistance in the electrically conductive band of material being indicative of a presence of a leaked fluid.

13. A computer-implemented method comprising:
detecting, by one or more leakage sensors a presence of a fluid in contact with the one or more leakage sensors, the one or more leakage sensors being embedded proximate to a microchip on a printed circuit board of a computing system; and
notifying, by the one or more leakage sensors, a baseboard management controller (BMC) embedded on the printed circuit board that a fluid leak has occurred.

14. The computer-implemented method of claim 13, further comprising in response to the detection of a fluid leak, transmitting, by the BMC, a signal to cause shutdown of one or more components of the computing system.

15. The computer-implemented method of claim 13, further comprising:
detecting, by the one or more leakage sensors, a location of the fluid leak with respect to the computing system; and
transmitting, via the BMC, a signal to cause shutdown of a respective portion of the computing system associated with the location of the fluid leak.

16. The computer-implemented method of claim 13, wherein the one or more leakage sensors are configured to define a boundary, the boundary enclosing a portion of the PCB that contains the microchip.

17. The computer-implemented method of claim 16, wherein only the microchip is within the boundary.

18. The computer-implemented method of claim 13, wherein the one or more leakage sensors includes one or more wires configured to transmit an electrical current, a change in resistance across the one or more wires being indicative of a presence of a leaked fluid.

19. The computer-implemented method of claim 13, wherein the one or more leakage sensors includes an electrically conductive band of material, a change in resistance in the electrically conductive band of material being indicative of a presence of a leaked fluid.

20. The computer-implemented method of claim 13, further comprising activating a mechanism for containing the fluid leak.
